(19) United States
(12) Patent Application Publication
(10) Pub. No.: US 2026/0290247 A1
(43) Pub. Date: Sep. 24, 2026

(54) DISPLAY PANEL AND DISPLAY DEVICE

(71) Applicant: Wuhan China Star Optoelectronics Semiconductor Display Technology Co., Ltd., Wuhan, Hubei (CN)

(72) Inventors: Junsong CHEN, Wuhan, Hubei (CN); Fei CHEN, Wuhan, Hubei (CN)

(21) Appl. No.: 18/577,257

(22) PCT Filed: Dec. 18, 2023
(86) PCT No.: PCT/CN2023/139486

§ 371 Date: May 3, 2026

(30) Foreign Application Priority Data
Dec. 13, 2023 (CN) 202311715969.2

(51) Int. Cl. G09G 3/3266; G09G 3/32

(52) U.S. Cl. CPC G09G 3/3266; G09G 3/32; G09G 2300/0819; G09G 2310/0245; G09G 2310/0267; G09G 2330/021; G09G 2360/148

(57) ABSTRACT

The present application discloses a display panel and a display device. The display panel operates through the optical sensors, reusing the first gate electrode driving signal and the second gate electrode driving signal provided by the gate electrode driver circuit for pixel circuits. Even with the addition of optical sensors, there is no need to set up additional driver circuits for optical sensors. This not only reduces power consumption but also minimizes frame occupation space.

### FIELD OF INVENTION

The present application relates to a field of display technologies, especially to a display panel and a display device.

### BACKGROUND OF INVENTION

Optical sensors, with their applications in remote light interaction, gesture sensing, ambient light sensing, and personal identification, can enhance the functionality of display panels.

However, adding optical sensors also requires the additional installation of corresponding driver circuits in the display panel. This not only increases the power consumption of the display panel but also expands its frame occupation space.

### SUMMARY OF INVENTION

The present application provides a display panel and a display device to mitigate a technical issue of increased optical sensors resulting in power consumption and increased frame occupation space.

In a first aspect, the present application provides a display panel, the display panel comprises first gate electrode driving lines configured to transmit first gate electrode driving signals, second gate electrode driving lines configured to transmit second gate electrode driving signals, a gate electrode driver circuit, pixel circuits, and optical sensors. The gate electrode driver circuit is electrically connected to the first gate electrode driving lines and the second gate electrode driving lines. The gate electrode driver circuit provides the first gate electrode driving signal and the second gate electrode driving signal. One pixel circuit is electrically connected to one of the first gate electrode driving lines and one of the second gate electrode driving lines. One optical sensor is electrically connected to one of the first gate electrode driving lines and to one of the second gate electrode driving lines. The optical sensor is configured to reset and control read-out respectively according to the first gate electrode driving signal and the second gate electrode driving signal.

In a second aspect, the present application provides a display device, the display device comprises the display panel of the above at least an embodiment. The display panel further comprises a display region, and the pixel circuits and the optical sensors are arranged in arrays in a display region.

### DESCRIPTION OF DRAWINGS

FIG. 1 is a first schematic structural view of a display panel provided by the embodiment of the present application.

FIG. 2 is a second schematic structural view of the display panel provided by the embodiment of the present application.

FIG. 3 is a schematic structural view of display panel as shown FIG. 2.

FIG. 4 is a first circuit diagram of optical sensors provided by the embodiment of the present application.

FIG. 5 is a second circuit diagram of the optical sensors provided by embodiment of the present application.

FIG. 6 is a schematic time chart of an optical sensor of a related art.

FIG. 7 is a schematic time chart of an optical sensor provided by the embodiment of the present application.

FIG. 8 is a schematic view of time chat after improvement in comparison to FIG. 7 before improvement.

FIG. 9 is a circuit diagram of a pixel circuit provided by the embodiment of the present application.

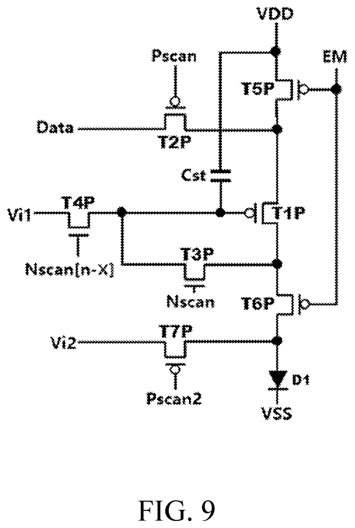

### DETAILED DESCRIPTION OF PREFERRED EMBODIMENTS

To make the objective, the technical solution, and the effect of the present application clearer and more explicit, the present application will be further described in detail below with reference to the accompanying drawings. It should be understood that the specific embodiments described here are only used to explain the present application instead of being used to limit the present application.

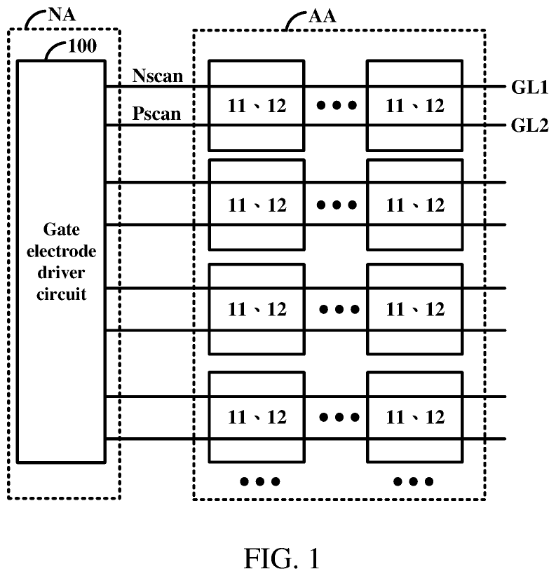

The present embodiment provides a display panel. With reference to FIGS. 1 to 8, as shown in FIG. 1, the display panel comprises a gate electrode driver circuit 100 and optical sensors 11. The gate electrode driver circuit 100 provides a first gate electrode driving signal Nscan and a second gate electrode driving signal Pscan for display. The optical sensors 11 are electrically connected to the gate electrode driver circuit 100. The optical sensors 11 reset and control read-out respectively according to the first gate electrode driving signal Nscan and the second gate electrode driving signal Pscan.

It can be understood that the display panel provided by the present embodiment, by the optical sensors 11, reuse the first gate electrode driving signal Nscan and the second gate electrode driving signal Pscan provided by the gate electrode driver circuit 100 for pixel circuits 12 to work. Even under a condition of the increased optical sensors 11, additionally setting corresponding driver circuits for the optical sensors 11 is not required, which not only lowers a power consumption, but also reduces a frame occupation space.

It should be explained that the display panel can further comprise pixel circuits 12 located in a display region AA. The pixel circuits 12 are electrically connected to a gate electrode driver circuit 100. The pixel circuits 12 are configured to display according to a first gate electrode driving signal Nscan and a second gate electrode driving signal Pscan.

Each of the pixel circuits comprises at least one N channel type transistor and at least one P channel type transistor. A gate electrode of one N channel type transistor is connected to a first gate electrode driving line GL1 to receive the first gate electrode driving signal Nscan. A gate electrode of oneP channel type transistor is connected to a second gate electrode driving line GL2 to receive the second gate electrode driving signal Pscan.

The above the gate electrode driver circuit 100 can be located in a non-display region NA (frame region) on a side of the display region AA. In some embodiments, the pixel circuits 12 can be arranged in an array in the display region AA. The optical sensors 11 can be located in the display region AA, and can be located in the non-display region NA. Under a condition of the optical sensors 11 located in the display region AA, the optical sensors 11 can be integrated in an array substrate of the display panel, which improves an integration degree of the display panel. In some embodiments, the optical sensors 11 can also be arranged in an array in the display region AA, each of the optical sensors 11 is integrated in at least one the pixel circuits 12, for example, every N ones of the pixel circuits 12 are integrated with one optical sensor 11, N can be a positive integer, for example 1, 2, 3, 4, 5 . . . etc.

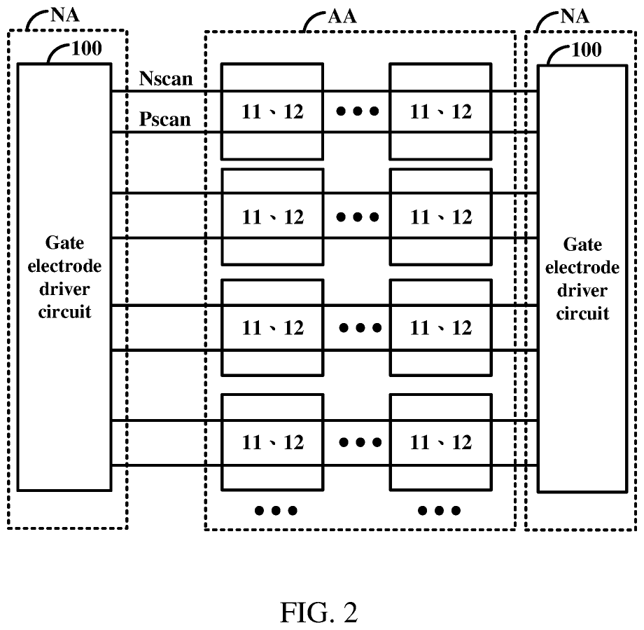

The gate electrode driver circuit 100 can comprise a plurality of shift registers that are cascaded, each of the shift registers can provide the first gate electrode driving signal Nscan and the second gate electrode driving signal Pscan respectively via the first gate electrode driving lines GL1 and the second gate electrode driving lines GL2. It can be understood that compared to the display panel as shown in FIG. 2, the display panel as shown in FIG. 1 lacks a gate electrode driver circuit 100 and can therefore reduce a frame occupation space.

Under a condition of scanning row by row, the optical sensors 11 and the pixel circuits 12 in the same row are electrically connected to one first gate electrode driving line GL1 and one second gate electrode driving line GL2. As such, each reset interval time and each acquisition interval time of the optical sensor 11 can keep consistent.

In one of the embodiments, with reference to FIG. 2, the display panel comprises two the same gate electrode driver circuits 100 that are located respectively in the non-display regions NA on two opposite sides of the display region AA. Two ends of each of the first gate electrode driving lines GLI and the second gate electrode driving lines GL2 are electrically connected to the two gate electrode driver circuits 100 to provide, from each of the two ends, one first gate electrode driving signal Nscan to the first gate electrode driving line GL1, and provide, from each of the two ends, one second gate electrode driving signal Pscan to the second gate electrode driving line GL2. This can reduce latency in transmission of the first gate electrode driving signal Nscan and the second gate electrode driving signal Pscan and facilitate increasing a charging time of the pixel circuits 12 and increase a reset time of the optical sensors 11 and accuracy of an output time.

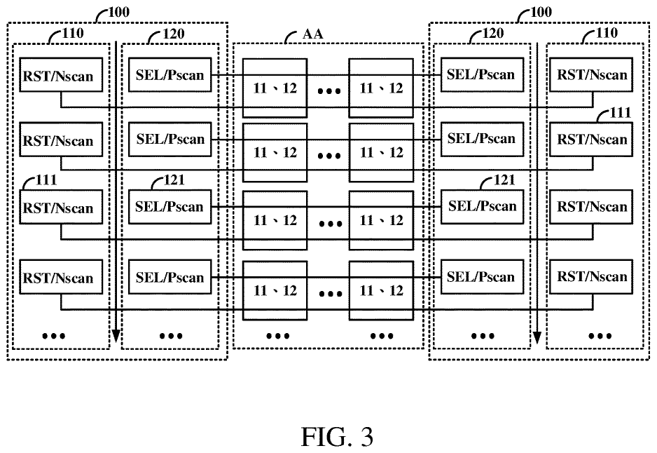

In one of the embodiments, with reference to FIG. 3, each gate electrode driver circuit 100 in FIG. 2 comprises a first gate electrode driver circuit 110 and a second gate electrode driver circuit 120. The first gate electrode driver circuit 110 comprises a plurality of first shift registers 111 that are cascaded. The second gate electrode driver circuit 120 comprises a plurality of second shift registers 121 that are cascaded. Each of the first gate electrode driving lines GL1 is electrically connected to two of the first shift registers 111, one row of the pixel circuits 12, and one row of the optical sensors 11. Each of the second gate electrode driving lines GL2 is electrically connected to two of the second shift registers 121, one row of the pixel circuits 12, one row of the optical sensors 11.

The first gate electrode driving signal Nscan serves as a reset control signal RST of the optical sensor 11, and the second gate electrode driving signal Pscan serves as a selection control signal SEL of the optical sensor 11.

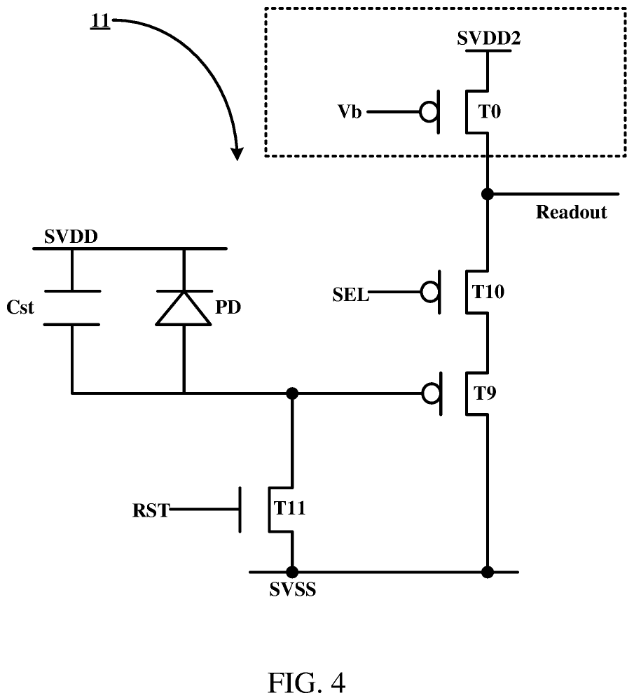

In one of the embodiments, with reference to FIG. 4, the optical sensors 11 comprises a photosensitive device PD, a first capacitor Cst, a first reset transistor T11, an amplifier transistor T9, and a selection transistor T10. A a terminal of the photosensitive device PD is electrically connected to a first power positive terminal SVDD. A terminal of the first capacitor Cst is electrically connected to a terminal of the photosensitive device PD. Another terminal of the first capacitor Cst is electrically connected to another terminal of the photosensitive device PD. A first electrode of the first reset transistor T11 is electrically connected to another terminal of the photosensitive device PD. A second electrode of the first reset transistor T11 is electrically connected to a first power negative terminal SVSS. A gate electrode of the first reset transistor T11 receives the reset control signal RST. A first electrode of the amplifier transistor T9 is electrically connected to the second electrode of the first reset transistor T11. A gate electrode of the amplifier transistor T9 is electrically connected to the first electrode of the first reset transistor T11. A first electrode of the selection transistor T10 is electrically connected to a second electrode of the amplifier transistor T9. A gate electrode of the selection transistor T10 receives the selection control signal SEL. A second electrode of the selection transistor T10 outputs a read-out signal Readout.

It should be explained that the reset control signal RST is the first gate electrode driving signal Nscan, and the selection control signal SEL is the second gate electrode driving signal Pscan.

The first electrode can be one of the source electrode and the drain electrode. The second electrode can be the other of the source electrode and the drain electrode. For example, in the case where the first electrode is the source electrode, the second electrode is the drain electrode. Alternatively, in the case where the first electrode is the drain electrode, the second electrode is the source electrode.

The photosensitive device PD can be a photosensitive diode (photodiode) or a photosensitive transistor.

In some embodiments, both the amplifier transistor T9 and the selection transistor T10 can be amorphous silicon thin film transistors of the P channel type. It can be understood that optical sensors 11 based on an amorphous silicon (a-Si) thin film transistor (TFT) can have advantages such as mature processing technology, high uniformity over large areas, low cost, high responsiveness, high signal-to-noise ratio, and small size. The first reset transistor T11 can be an N-channel oxide thin film transistor, which can better prevent leakage of a light-induced current from the photosensitive device PD.

In another some embodiments, both the amplifier transistor T9 and the selection transistor T10 can be oxide thin film transistors. The first reset transistor T11 can also be an amorphous silicon thin film transistor.

In some embodiments, with reference to FIG. 4, the optical sensors 11 further comprises a divider transistor T0. A first electrode of the divider transistor T0 is electrically connected to a second electrode of the selection transistor T10. A second electrode of the divider transistor T0 is electrically connected to second power positive terminal SVDD2. A gate electrode of the divider transistor T0 receives a divider control signal Vb.

It should be explained that the divider transistor T0 is configured to adjust a voltage range and/or a current range of the read-out signal Readout to match an identification range of a read circuit or a read-out chip receiving a read signal.

The divider transistor T0 can be integrated in a corresponding chip to reduce an inner side occupation space. The divider transistor T0 can be a thin film transistor of a N channel or a P channel, for example, an amorphous silicon or oxide thin film transistor.

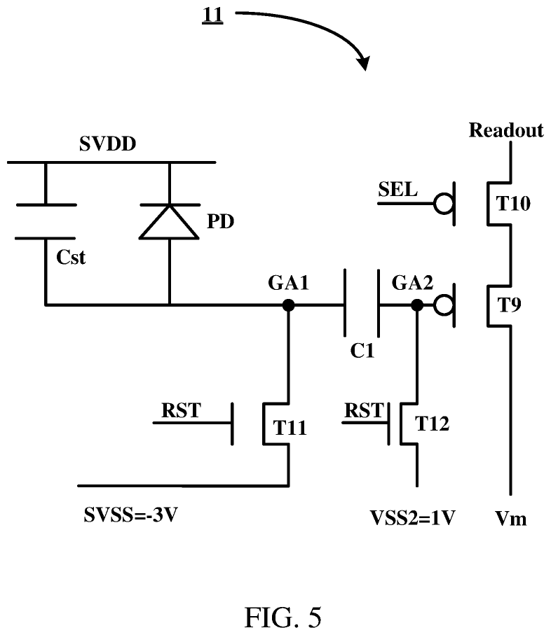

In one of the embodiments, with reference to FIG. 5, the optical sensors 11 comprises the photosensitive device PD, the first capacitor Cst, the first reset transistor T11, a second capacitor C1, a second reset transistor T12, the amplifier transistor T9, and the selection transistor T10. A terminal of the photosensitive device PD is electrically connected to the first power positive terminal SVDD. A terminal of the first capacitor Cst is electrically connected to a terminal of the photosensitive device PD. Another terminal of the first capacitor Cst is electrically connected to another terminal of the photosensitive device PD. The first electrode of the first reset transistor T11 is electrically connected to another terminal of the photosensitive device PD. The second electrode of the first reset transistor T11 is electrically connected to the first power negative terminal SVSS. The gate electrode of the first reset transistor T11 receives the reset control signal RST. A terminal of the second capacitor C1 is electrically connected to the first electrode of the first reset transistor T11. The first electrode of the first reset transistor T11 is electrically connected to another terminal of the second capacitor C1. The second electrode of the first reset transistor T11 is electrically connected to a second power negative terminal VSS2. The gate electrode of the first reset transistor T11 is electrically connected to the gate electrode of the first reset transistor T11. The first electrode of the amplifier transistor T9 is electrically connected to voltage terminal Vm. The gate electrode of the amplifier transistor T9 is electrically connected to another terminal of the second capacitor C1. The first electrode of the selection transistor T10 is electrically connected to the second electrode of the amplifier transistor T9. The gate electrode of the selection transistor T10 receives the selection control signal SEL, and the second electrode of the selection transistor T10 outputs the read-out signal Readout.

It should be explained that in the present embodiment, a channel type of the first reset transistor T11 is the same as a channel type of the second reset transistor T12.

The first capacitor Cst is configured to store the light-induced current of the photosensitive device PD, and bias an electric potential of a node GA1 from an electric potential of the first power negative terminal SVSS to an electric potential of the first power positive terminal SVDD. The second capacitor C1, while performing an obstruction effect, also uses a bootstrap effect itself to transmit the light-induced current of the photosensitive device PD from the node GA1 to a node GA2.

To match a voltage range or a current range of the read-out signal Readout, an electric potential of the second power negative terminal VSS2 is higher than an electric potential of the first power negative terminal SVSS. For example, the electric potential of the first power negative terminal SVSS can be −3V, and the electric potential of the second power negative terminal VSS 2 can be 1V. It is because of a layout space and the optical sensors 11 requiring a voltage difference, the voltage difference would result in a worse leakage current. As such, a voltage range of the node GA1 is about −1 to −3V (a condition without including −3V), which would lower a conversion efficiency of the amplifier transistor T9, and a voltage range or a current range of the read-out signal Readout would be at an edge of a detecting ability of the read-out circuit or the read-out chip, which easily results in read-out failure of the read-out circuit or the read-out chip.

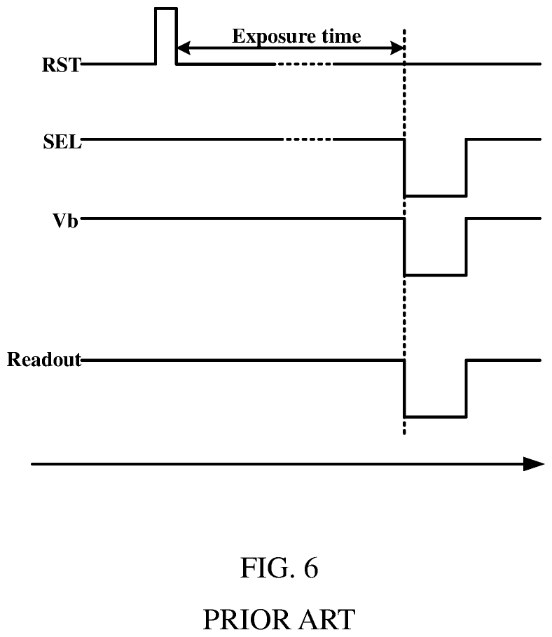

FIG. 6 is a schematic time chart of an optical sensor of a related art. Under a condition of an arrival of a positive pulse of the reset control signal RST, the first reset transistor T11 or the first reset transistor T11 and the second reset transistor T12 switch on to reset an electric potential of another terminal of the photosensitive device PD. After undergoing an exposure time, a negative pulse of the selection control signal SEL and the divider control signal Vb arrives, the selection transistor T10 and the divider transistor T0 switch on, and the amplifier transistor T9 amplifies and outputs the light-induced current of the photosensitive device PD as the read-out signal Readout.

The exposure time is an interval time between a falling edge of the reset control signal RST and a rising edge of the selection control signal SEL.

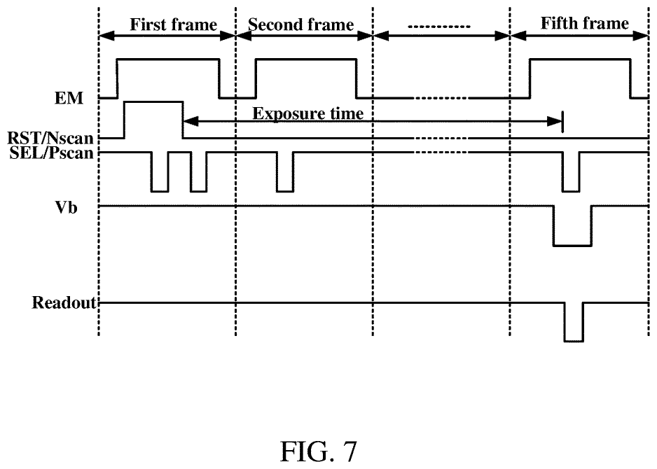

FIG. 7 is a schematic time chart of an optical sensor 11 provided by the embodiment of the present application. The display panel further comprises a driver chip and a touch module. The touch module is connected to the optical sensors 11 and the driver chip. The driver chip is connected to the gate electrode driver circuit 100. The touch module correspondingly outputs a detective signal according to the detected read-out signal Readout outputted by the optical sensor 11. The driver chip, according to the detective signal, controls the first gate electrode driving signal Nscan and the second gate electrode driving signal Pscan outputted by the gate electrode driver circuit 100 to lower a display refresh frequency such that the optical sensors 11, after undergoing the exposure time, outputs the read-out signal Readout. The driver chip increases a driving voltage and/or a light emission current of the pixel circuits 12 according to the detective signal to increase display brightness.

It should be explained that under a condition that a touch action is detected, the display panel increases display brightness. The greater the brightness is, the greater a light intensity is. As such, the optical sensors 11 can comprise a faster responsive time. Also, because the refresh frequency is lowered, a positive pulse of the first gate electrode driving signal Nscan/the reset control signal RST will not be presented at least one frame later, the optical sensors 11 also will not be reset again, which can achieve a longer exposure time.

In the case of detecting a touch action (for example, fingerprint), performing fingerprint recognition through the optical sensors 11, as opposed to conducting fingerprint recognition through the optical sensors 11 when no fingerprint is detected, can reduce power consumption.

The refresh frequency changes positively with exposure time. For example, when the refresh frequency is below 24 Hz, the exposure time can be greater than 30 ms. From this, it can be understood that the exposure time can be increased or decreased by altering the refresh frequency.

Later, after the exposure time is completed, a negative pulse of the second gate electrode driving signal Pscan/the selection control signal SEL switches on a selection control transistor, and the optical sensor 11 outputs the read-out signal Readout. In FIG. 4, under the control of the negative pulse of the divider control signal Vb, the divider transistor T0, switching on, outputs the read-out signal Readout.

EM is a light emission control signal of the pixel circuits 12. Under a condition of EM in a high electric potential, the pixel circuit 12 emits no light. Under a condition of EM in low electric potential, the pixel circuit 12 emits light.

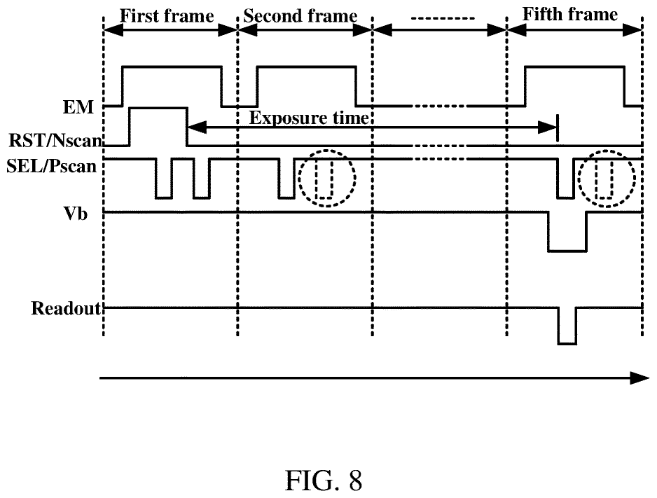

FIG. 8 is a schematic view of time chat after improvement in comparison to FIG. 7 before improvement. Before improvement, the second gate electrode driving signal Pscan/the selection control signal SEL in each frame comprises two negative pulses. After the improvement, the second gate electrode driving signal Pscan/the selection control signal SEL only, in a first frame (write frame) after decrease of the refresh frequency, comprises two negative pulses, and in a second frame . . . a fifth frame, only comprises one negative pulse.

As such, the first gate electrode driving signal Nscan comprises a positive pulse. The first reset transistor T11 is an N channel type transistor. A gate electrode of the first reset transistor T11 receives the first gate electrode driving signal Nscan to reset the optical sensors 11. The second gate electrode driving signal Pscan comprises a negative pulse, the selection transistor T10 is a P channel type transistor. A gate electrode of the selection transistor T10 receives the second gate electrode driving signal Pscan to control output of the read-out signal Readout.

In one of the embodiments, the pixel circuits 12 can comprise at least one of a write transistor T2P, a driver transistor T1P, a first light emission control transistor T5P, a second light emission control transistor T6P, a first initialization transistor T4P, a second initialization transistor T7P, a compensation transistor T3P, a light emitting device D1, and a storage capacitor Cst.

A first power line is electrically connected to a first electrode of the first light emission control transistor T5P and a terminal of the storage capacitor Cst. A second electrode of the first light emission control transistor T5P is electrically connected to a first electrode of the driver transistor TIP and a first electrode of the write transistor T2P. A second electrode of the driver transistor TIP is electrically connected to a first electrode of the compensation transistor T3P and a first electrode of the second light emission control transistor T6P. A second electrode of the second light emission control transistor T6P is electrically connected to a first electrode of the second initialization transistor T7P and an anode of the light emitting device D1. A cathode of the light emitting device D1 is electrically connected to a second power line. A light emission control line is electrically connected to a gate electrode of the first light emission control transistor T5P and a gate electrode of the second light emission control transistor T6P. A second electrode of the write transistor T2P is electrically connected to a data line. A gate electrode of the write transistor T2P is electrically connected to a first scan line. A second electrode of the second initialization transistor T7P is electrically connected to a second initialization line. A gate electrode of the second initialization transistor T7P is electrically connected to a second scan line. A second electrode of the compensation transistor T3P is electrically connected to a gate electrode of the driver transistor T1P. A gate electrode of the compensation transistor T3P is electrically connected to a third scan line. A gate electrode of the driver transistor TIP is electrically connected to another terminal of the storage capacitor Cst and a first electrode of the first initialization transistor T4P. A second electrode of the first initialization transistor T4P is electrically connected to a first initialization line. A gate electrode of the first initialization transistor T4P is electrically connected to a fourth scan line.

The first electrode can be one of a source electrode and a drain electrode, and the second electrode can be the other of the source electrode and the drain electrode. For example, when the first electrode is a source electrode, the second electrode is a drain electrode. Alternatively, when the first electrode is a drain electrode, the second electrode is a source electrode.

The first power line is configured to transmit a power positive signal VDD, and the second power line is configured to transmit a power negative signal VSS. An electric potential of the power positive signal VDD is higher than an electric potential of the power negative signal VSS. The data line is configured to transmit data signal Data. The light emission control line is configured to transmit light emission control signal EM. The first initialization line is configured to transmit a first initialization signal Vi1. The second initialization line is configured to transmit a second initialization signal Vi2. The first scan line is configured to transmit the second gate electrode driving signal Pscan. The second scan line is configured to transmit a scan signal Pscan2. The third scan line is configured to transmit the first gate electrode driving signal Nscan. The fourth scan line is configured to transmit a scan signal Nscan [n-X] , and X is an integer greater than or equal to 1.

The write transistor T2P is a P channel type thin film transistor, in particular can be a polycrystalline silicon thin film transistor, for example, a low-temperature polycrystalline silicon thin film transistor. The first initialization transistor T4P or the compensation transistor T3P is an N channel type thin film transistor, in particular can be oxide thin film transistor, for example indium gallium zinc oxide thin film transistor. At least one of the driver transistor TIP, the first light emission control transistor T5P, the second light emission control transistor T6P, and the second initialization transistor T7P can be a P channel type thin film transistor or an N channel type thin film transistor.

In one of the embodiments, the present embodiment provides a display device, the display device comprises the display panel in the above at least one embodiment.

It can be understood that, in the display device provided by the present embodiment, it includes the display panel in at least one embodiment mentioned above. Similarly, it can operate through the optical sensors 11 by reusing the first gate electrode driving signal Nscan and the second gate electrode driving signal Pscan provided by the gate electrode driver circuit 100 for display. Even in the case of adding the optical sensors 11, there is no need to additionally set corresponding driver circuits for the optical sensors 11. This not only reduces power consumption but also decreases frame occupation space.

The display panel can be an organic light emitting diode display panel, a mini-light emitting diode display panel, a micro light emitting diode display panel, a quantum dot light emitting diode display panel, etc.

It can be understood that for a person of ordinary skill in the art, equivalent replacements or changes can be made according to the technical solution of the present application and its inventive concept, and all these changes or replacements should belong to the scope of protection of the appended claims of the present application.

1. A display panel, wherein the display panel comprises:
first gate electrode driving lines configured to transmit first gate electrode driving signals;
second gate electrode driving lines configured to transmit second gate electrode driving signals;
a gate electrode driver circuit, wherein the gate electrode driver circuit is electrically connected to the first gate electrode driving lines and the second gate electrode driving lines, and the gate electrode driver circuit provides the first gate electrode driving signal, the second gate electrode driving signal;
pixel circuits, wherein each of the pixel circuits is electrically connected to one of the first gate electrode driving lines and one of the second gate electrode driving lines; and
optical sensors, wherein each of the optical sensors is electrically connected to one of the first gate electrode driving lines and one of the second gate electrode driving lines, the optical sensors are configured to rest and control read-out according to the first gate electrode driving signal and the second gate electrode driving signal.

2. The display panel according to claim 1, wherein the optical sensor comprises:
a photosensitive device, wherein a terminal of the photosensitive device is electrically connected to a first power positive terminal;
a first capacitor, wherein a terminal of the first capacitor is electrically connected to a terminal of the photosensitive device, and another terminal of the first capacitor is electrically connected to another terminal of the photosensitive device;
a first reset transistor, wherein a first electrode of the first reset transistor is electrically connected to another terminal of the photosensitive device, a second electrode of the first reset transistor is electrically connected a first power negative terminal, and a gate electrode of the first reset transistor receives the first gate electrode driving signal;
an amplifier transistor, wherein a first electrode of the amplifier transistor is electrically connected to the second electrode of the first reset transistor, and a gate electrode of the amplifier transistor is electrically connected to a first electrode of the first reset transistor; and
a selection transistor, wherein a first electrode of the selection transistor is electrically connected to a second electrode of the amplifier transistor, and a gate electrode of the selection transistor receives the second gate electrode driving signal, and a second electrode of the selection transistor is configured to output a read-out signal.

3. The display panel according to claim 2, wherein the optical sensor further comprises a divider transistor, a first electrode of the divider transistor is electrically connected to the second electrode of the selection transistor, a second electrode of the divider transistor is electrically connected to a second power positive terminal, and a gate electrode of the divider transistor receives a divider control signal.

4. The display panel according to claim 1, wherein the optical sensor comprises:
a photosensitive device, wherein a terminal of the photosensitive device is electrically connected to a first power positive terminal;
a first capacitor, wherein a terminal of the first capacitor is electrically connected to a terminal of the photosensitive device, and another terminal of the first capacitor is electrically connected to another terminal of the photosensitive device;
a first reset transistor, wherein a first electrode of the first reset transistor is electrically connected to another terminal of the photosensitive device, a second electrode of the first reset transistor is electrically connected a first power negative terminal, and a gate electrode of the first reset transistor receives the first gate electrode driving signal;
a second capacitor, wherein a terminal of the second capacitor is electrically connected to the first electrode of the first reset transistor;
a second reset transistor, wherein the first electrode of the first reset transistor is electrically connected to another terminal of the second capacitor, the second electrode of the first reset transistor is electrically connected to a second power negative terminal, and the gate electrode of the first reset transistor is electrically connected to the gate electrode of the first reset transistor;
an amplifier transistor, wherein a first electrode of the amplifier transistor is electrically connected to a voltage terminal, and a gate electrode of the amplifier transistor is electrically connected to another terminal of the second capacitor; and
a selection transistor, wherein a first electrode of the selection transistor is electrically connected to a second electrode of the amplifier transistor, and a gate electrode of the selection transistor receives the second gate electrode driving signal, and a second electrode of the selection transistor is configured to output a read-out signal.

5. The display panel according to claim 4, wherein a channel type of the first reset transistor is the same as a channel type of the second reset transistor.

6. The display panel according to claim 5, wherein an electric potential of the second power negative terminal is higher than an electric potential of the first power negative terminal.

7. The display panel according to claim 2, wherein the first gate electrode driving signal controls the first reset transistor to reset the optical sensors; and the second gate electrode driving signal controls the selection transistor to control output of the read-out signal.

8. The display panel according to claim 7, wherein the first gate electrode driving signal comprises a positive pulse, the first reset transistor is an N channel type transistor, and the gate electrode of the first reset transistor receives the first gate electrode driving signal; and
the second gate electrode driving signal comprises a negative pulse, the selection transistor is a P channel type transistor, and the gate electrode of the selection transistor receives the second gate electrode driving signal.

9. The display panel according to claim 8, wherein each of the pixel circuits comprises at least one N channel type transistor and at least one P channel type transistor, a gate electrode of the N channel type transistor is connected to the first gate electrode driving line to receive the first gate electrode driving signal, and a gate electrode of the P channel type transistor is connected to the second gate electrode driving lines to receive the second gate electrode driving signal.

10. The display panel according to claim 1, wherein the display panel further comprises a driver chip and a touch module, the touch module is connected to the optical sensors and the driver chip, the driver chip is connected to the gate electrode driver circuit, the touch module correspondingly outputs a detective signal according to a detected read-out signal outputted by the optical sensor, the driver chip controls the first gate electrode driving signal and the second gate electrode driving signal outputted by the gate electrode driver circuit to lower a display the refresh frequency according to the detective signal such that the optical sensors, after undergoing an exposure time, outputs a read-out signal.

11. The display panel according to claim 10, wherein the refresh frequency changes positively with the exposure time.

12. The display panel according to claim 10, wherein the driver chip increases a driving voltage and/or a light emission current of the pixel circuits according to the detective signal to increase display brightness.

13. A display device, comprising a display panel, comprising:
first gate electrode driving lines configured to transmit first gate electrode driving signals;
second gate electrode driving lines configured to transmit second gate electrode driving signals;
a gate electrode driver circuit, wherein the gate electrode driver circuit is electrically connected to the first gate electrode driving lines and the second gate electrode driving lines. and the gate electrode driver circuit provides the first gate electrode driving signal, the second gate electrode driving signal;
pixel circuits, wherein each of the pixel circuits is electrically connected to one of the first gate electrode driving lines and one of the second gate electrode driving lines; and
optical sensors, wherein each of the optical sensors is electrically connected to one of the first gate electrode driving lines and one of the second gate electrode driving lines, the optical sensors are configured to rest and control read-out according to the first gate electrode driving signal and the second gate electrode driving signal;
wherein the display panel further comprises a display region, and the pixel circuits and the optical sensors are arranged in arrays the display region.

14. The display device according to claim 13, wherein the optical sensor comprises:
a photosensitive device, wherein a terminal of the photosensitive device is electrically connected to a first power positive terminal;
a first capacitor, wherein a terminal of the first capacitor is electrically connected to a terminal of the photosensitive device, and another terminal of the first capacitor is electrically connected to another terminal of the photosensitive device;
a first reset transistor, wherein a first electrode of the first reset transistor is electrically connected to another terminal of the photosensitive device, a second electrode of the first reset transistor is electrically connected a first power negative terminal, and a gate electrode of the first reset transistor receives the first gate electrode driving signal;
an amplifier transistor, wherein a first electrode of the amplifier transistor is electrically connected to the second electrode of the first reset transistor, and a gate electrode of the amplifier transistor is electrically connected to a first electrode of the first reset transistor; and
a selection transistor, wherein a first electrode of the selection transistor is electrically connected to a second electrode of the amplifier transistor, and a gate electrode of the selection transistor receives the second gate electrode driving signal, and a second electrode of the selection transistor is configured to output a read-out signal.

15. The display device according to claim 14, wherein the optical sensor further comprises a divider transistor, a first electrode of the divider transistor is electrically connected to the second electrode of the selection transistor, a second electrode of the divider transistor is electrically connected to a second power positive terminal, and a gate electrode of the divider transistor receives a divider control signal.

16. The display device according to claim 13, wherein the optical sensor comprises:
a photosensitive device, wherein a terminal of the photosensitive device is electrically connected to a first power positive terminal;
a first capacitor, wherein a terminal of the first capacitor is electrically connected to a terminal of the photosensitive device, and another terminal of the first capacitor is electrically connected to another terminal of the photosensitive device;
a first reset transistor, wherein a first electrode of the first reset transistor is electrically connected to another terminal of the photosensitive device, a second electrode of the first reset transistor is electrically connected a first power negative terminal, and a gate electrode of the first reset transistor receives the first gate electrode driving signal;
a second capacitor, wherein a terminal of the second capacitor is electrically connected to the first electrode of the first reset transistor;
a second reset transistor, wherein the first electrode of the first reset transistor is electrically connected to another terminal of the second capacitor, the second electrode of the first reset transistor is electrically connected to a second power negative terminal, and the gate electrode of the first reset transistor is electrically connected to the gate electrode of the first reset transistor;
an amplifier transistor, wherein a first electrode of the amplifier transistor is electrically connected to a voltage terminal, and a gate electrode of the amplifier transistor is electrically connected to another terminal of the second capacitor; and
a selection transistor, wherein a first electrode of the selection transistor is electrically connected to a second electrode of the amplifier transistor, and a gate electrode of the selection transistor receives the second gate electrode driving signal, and a second electrode of the selection transistor is configured to output a read-out signal.

17. The display device according to claim 16, wherein a channel type of the first reset transistor is the same as a channel type of the second reset transistor.

18. The display device according to claim 17, wherein an electric potential of the second power negative terminal is higher than an electric potential of the first power negative terminal.

19. The display device according to claim 14, wherein the first gate electrode driving signal controls the first reset transistor to reset the optical sensors; and the second gate electrode driving signal controls the selection transistor to control output of the read-out signal.

20. The display device according to claim 19, wherein the first gate electrode driving signal comprises a positive pulse, the first reset transistor is an N channel type transistor, and the gate electrode of the first reset transistor receives the first gate electrode driving signal; and
the second gate electrode driving signal comprises a negative pulse, the selection transistor is a P channel type transistor, and the gate electrode of the selection transistor receives the second gate electrode driving signal.
